(19) United States
(12) Patent Application Publication
(10) Pub. No.: US 2009/0314208 A1
(43) Pub. Date: Dec. 24, 2009

(54) PEDESTAL HEATER FOR LOW TEMPERATURE PECVD APPLICATION

(75) Inventors: Jianhua Zhou, San Jose, CA (US); Lipyeow Yap, Santa Clara, CA (US); Dmitry Sklyar, San Jose, CA (US); Mohamad Ayoub, San Jose, CA (US); Karthik Janakiraman, San Jose, CA (US); Juan Carlos Rocha-Alvarez, San Carlos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/490,168

(22) Filed: Jun. 23, 2009

Related U.S. Application Data
(60) Provisional application No. 61/075,262, filed on Jun. 24, 2008.

(51) Int. Cl. C23C 16/54

(52) U.S. Cl. 118/723 R

(57) ABSTRACT

A method and apparatus for providing power to a heated support pedestal is provided. In one embodiment, a process kit is described. The process kit includes a hollow shaft made of a conductive material coupled to a substrate support at one end and a base assembly at an opposing end, the base assembly adapted to couple to a power box disposed on a semiconductor processing tool. In one embodiment, the base assembly comprises at least one exposed electrical connector disposed in an insert made of a dielectric material, such as a plastic resin.

### CROSS-REFERENCE TO RELATED APPLICATIONS

This application claims benefit of United States Provisional Patent Application Ser. No. 61/075,262 (Attorney Docket No. 013633L), filed Jun. 24, 2008, which is incorporated herein by reference.

### BACKGROUND OF THE INVENTION

1. Field of the Invention

Embodiments of the invention generally relate to a semiconductor processing chamber and, more specifically, heated support pedestal for a semiconductor processing chamber.

2. Description of the Related Art

Semiconductor processing involves a number of different chemical and physical processes whereby minute integrated circuits are created on a substrate. Layers of materials which make up the integrated circuit are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or other appropriate material.

In the manufacture of integrated circuits, plasma processes are often used for deposition or etching of various material layers. Plasma processing offers many advantages over thermal processing. For example, plasma enhanced chemical vapor deposition (PECVD) allows deposition processes to be performed at lower temperatures and at higher deposition rates than achievable in analogous thermal processes. Thus, PECVD is advantageous for integrated circuit fabrication with stringent thermal budgets, such as for very large scale or ultra-large scale integrated circuit (VLSI or ULSI) device fabrication.

The processing chambers used in these processes typically include a substrate support or pedestal disposed therein to support the substrate during processing. In some processes, the pedestal may include an embedded heater adapted to control the temperature of the substrate and/or provide elevated temperatures that may be used in the process. Conventionally, the pedestals may be made of a ceramic material, which generally provides desirable device fabrication results.

However, ceramic pedestals create numerous challenges. One of these challenges is elevated cost of ownership as the pedestal manufacturing cost accounts for a significant portion of the tool cost. Additionally, the use of ceramic to encapsulate the heater does not shield the heater from radio frequency (RF) power that may be used in the device fabrication process. Thus, if RF power is used in the device fabrication process, RF filters must be provided to shield the heater, which also increases tool cost.

Therefore, what is needed is a pedestal made of a material that is less costly and less expensive to manufacture, as well as providing RF shielding of an embedded heater.

### SUMMARY OF THE INVENTION

A method and apparatus for providing power to a heated support pedestal is provided. In one embodiment, a process kit is described. The process kit includes a hollow shaft made of a conductive material coupled to a substrate support at one end and a base assembly at an opposing end, the base assembly adapted to couple to a power box disposed on a semiconductor processing tool. In one embodiment, the base assembly comprises at least one exposed electrical connector disposed in an insert made of a dielectric material, such as a plastic resin.

In one embodiment, a pedestal for a semiconductor processing chamber is described. The pedestal includes a substrate support comprising a conductive material, a heating element encapsulated within the substrate support, and a hollow shaft comprising a conductive material coupled to the substrate support at a first end and a mating interface at an opposing end, the mating interface comprising a dielectric plug that includes at least one exposed electrical connector being adapted to couple to a power outlet disposed on the processing chamber and being electrically isolated from the hollow shaft.

In another embodiment, a pedestal for a semiconductor processing chamber is described. The pedestal includes a substrate support comprising a conductive material, a heating element encapsulated within the substrate support, a hollow shaft comprising a conductive material coupled to the substrate support at a first end and a base assembly at an opposing end. The base assembly includes a slotted conductive portion having an interior volume, and a dielectric plug disposed in the interior volume, the dielectric plug comprising one or more conductive members extending longitudinally therethrough, each of the one or more conductive members being electrically isolated from the slotted conductive portion.

In another embodiment, a pedestal for a semiconductor processing chamber is described. The pedestal includes a substrate support coupled to a hollow shaft, each of the substrate support and the hollow shaft comprising an aluminum material, the hollow shaft including at least two conductive leads coupled to a heating element encapsulated within the substrate support, and a base assembly coupled to the hollow shaft opposite the substrate support. The base assembly includes a slotted conductive portion having an interior volume, and a dielectric plug disposed in the interior volume, the dielectric plug comprising one or more conductive members extending longitudinally therethrough, each of the one or more conductive members being electrically coupled to at least one of the at least two conductive leads by a conductive insert disposed in an insulative jacket.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial cross sectional view of one embodiment of a plasma system.

FIG. 2A is an isometric top view of one embodiment of a pedestal shown in FIG. 1.

FIG. 2B is an isometric bottom view of one embodiment of the pedestal shown in FIG. 2A.

FIG. 3A is a cross sectional view of a portion of another embodiment of a pedestal.

FIG. 3B is an isometric exploded view of another embodiment of a pedestal.

FIG. 3C is a bottom isometric view of one embodiment of a base assembly.

FIG. 4 is a cross-sectional view of another embodiment of a base assembly.

FIG. 5 is schematic top view of a substrate support surface of the pedestals as described herein.

FIGS. 6A-6C are graphical representations of data taken from three separate heating profiles of a pedestal as described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention are illustratively described below in reference plasma chambers, In one embodiment, the plasma chamber is utilized in a plasma enhanced chemical vapor deposition (PECVD) system. Examples of PECVD systems that may be adapted to benefit from the invention include a PRODUCER® SE CVD system, a PRODUCER® GT™ CVD system or a DXZ® CVD system, all of which are commercially available from Applied Materials, Inc., Santa Clara, Calif. The Producer® SE CVD system (e.g., 200 mm or 300 mm) has two isolated processing regions that may be used to deposit thin films on substrates, such as conductive films, silanes, carbon-doped silicon oxides and other materials and is described in U.S. Pat. Nos. 5,855,681 and 6,495,233, both of which are incorporated by reference. The DXZ® CVD chamber is disclosed in U.S. Pat. No. 6,364,954, which is also incorporated by reference. Although the exemplary embodiment includes two processing regions, it is contemplated that the invention may be used to advantage in systems having a single processing region or more than two processing regions. It is also contemplated that the invention may be utilized to advantage in other plasma chambers, including etch chambers, ion implantation chambers, plasma treatment chambers, and stripping chambers, among others. It is further contemplated that the invention may be utilized to advantage in plasma processing chambers available from other manufacturers.

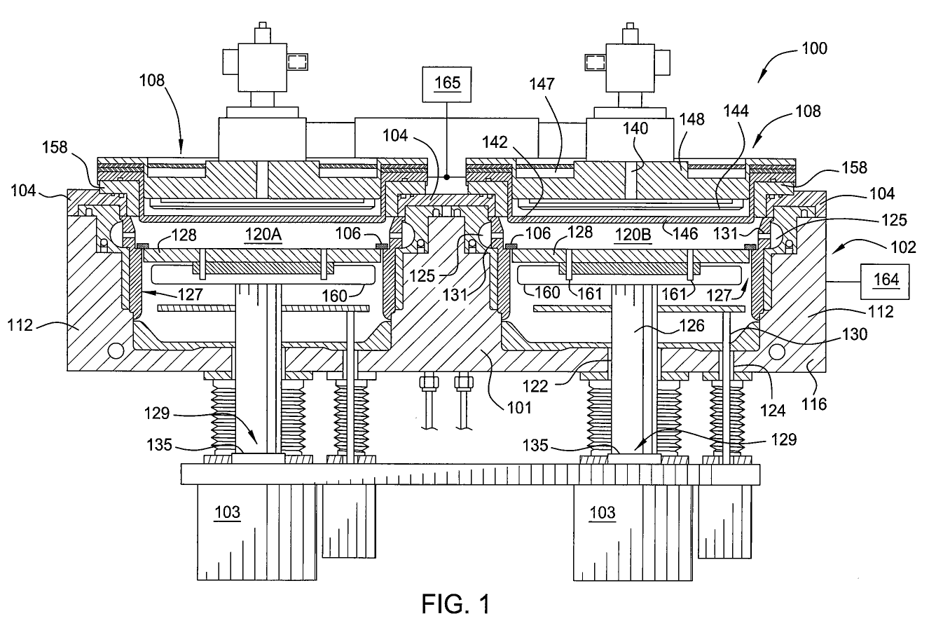

FIG. 1 is a partial cross sectional view of a plasma system 100. The plasma system 100 generally comprises a processing chamber body 102 having sidewalls 112, a bottom wall 116 and an interior sidewall 101 defining a pair of processing regions 120A and 120B. Each of the processing regions 120A-B is similarly configured, and for the sake of brevity, only components in the processing region 120B will be described.

A pedestal 128 is disposed in the processing region 120B through a passage 122 formed in the bottom wall 116 in the system 100. The pedestal 128 is adapted to support a substrate (not shown) on the upper surface thereof. The pedestal 128 may include heating elements, for example resistive elements, to heat and control the substrate temperature in a desired process temperature. Alternatively, the pedestal 128 may be heated by a remote heating element, such as a lamp assembly.

The pedestal 128 is coupled by a stem 126 to a power outlet or power box 103, which may include a drive system that controls the elevation and movement of the pedestal 128 within the processing region 120B. The stem 126 also contains electrical power interfaces to provide electrical power to the pedestal 128. The power box 103 also includes interfaces for electrical power and temperature indicators, such as a thermocouple interface. The stem 126 also includes a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is utilized to activate substrate lift pins 161 disposed through the pedestal 128. The substrate lift pins 161 selectively space the substrate from the pedestal to facilitate exchange of the substrate with a robot (not shown) utilized for transferring the substrate into and out of the processing region 120B through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146. A radio frequency (RF) source 165 is coupled to the showerhead assembly 142. The RF source 165 powers the showerhead assembly 142 to facilitate generation of a plasma between the faceplate 146 of the showerhead assembly 142 and the heated pedestal 128. In one embodiment, the RF source 165 may be a high frequency radio frequency (HFRF) power source, such as a 13.56 MHz RF generator. In another embodiment, RF source 165 may include a HFRF power source and a low frequency radio frequency (LFRF) power source, such as a 300 kHz RF generator. Alternatively, the RF source may be coupled to other portion of the processing chamber body 102, such as the pedestal 128, to facilitate plasma generation. A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120B in very close proximity to the sidewalls 101, 112 of the chamber body 102 to prevent exposure of the sidewalls 101, 112 to the processing environment within the processing region 120B. The liner assembly 127 includes a circumferential pumping cavity 125 that is coupled to a pumping system 164 configured to exhaust gases and byproducts from the processing region 120B and control the pressure within the processing region 120B. A plurality of exhaust ports 131 may be formed on the chamber liner assembly 127. The exhaust ports 131 are configured to allow the flow of gases from the processing region 120B to the circumferential pumping cavity 125 in a manner that promotes processing within the system 100.

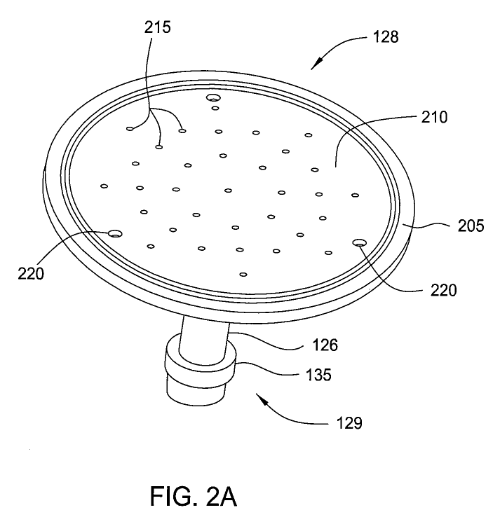

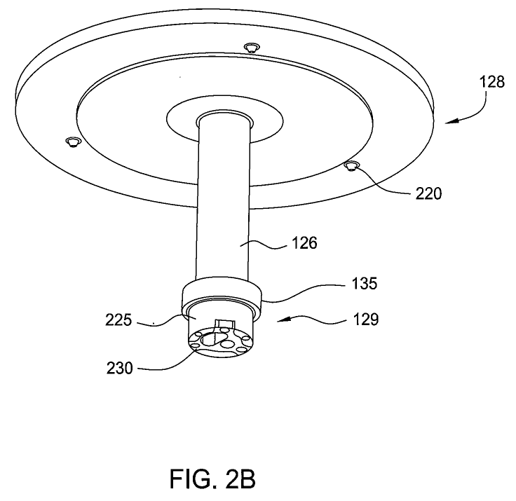

FIG. 2A is an isometric top view of one embodiment of a pedestal 128 that is utilized in the plasma system 100. The pedestal 128 includes a stem 126 and a base assembly 129 opposite a circular substrate support 205. In one embodiment, the stem 126 is configured as a tubular member or hollow shaft. In one embodiment, the base assembly 129 is utilized as a detachable mating interface with electrical connections disposed in or on the power outlet or power box 103. The substrate support 205 includes a substrate receiving surface or support surface 210 that is substantially planar. The support surface 210 may be adapted to support a 200 mm substrate, a 300 mm substrate, or a 450 mm substrate. In one embodiment, the support surface 210 includes a plurality of structures 215, which may be bumps or protrusions extending above the plane of the support surface 210. The height of each of the plurality of structures 215 are substantially equal to provide a substantially planar substrate receiving plane or surface that is slightly elevated or spaced-away from the support surface 210. In one embodiment, each of the structures 215 are formed of or coated with a material that is different from the material of the support surface 210. The substrate support 205 also includes a plurality of openings 220 formed therethrough that are adapted to receive a lift pin 161 (FIG. 1).

In one embodiment, the body of the substrate support 205 and stem 126 are made of a conductive metallic material while the base assembly 129 is made of a combination of a conductive metallic material and an insulative material. Fabricating the substrate support 205 from a conductive metallic material lowers the cost of ownership as compared to substrate supports made of ceramics. Additionally, the conductive metallic material serves to shield an embedded heater (not shown in this view) from RF power. This increases the efficiency and lifetime of the substrate support 205, which decreases cost of ownership.

In one embodiment, the body of the substrate support 205 and stem 126 are made solely of an aluminum material, such as an aluminum alloy. In a specific embodiment, both of the substrate support 205 and stem are made of 6061 Al. In one embodiment, the base assembly 129 comprises aluminum portions and insulative portions, such as a polyetheretherketone (PEEK) resin disposed therein to electrically insulate portions of the base assembly 129 from the conductive portions of the substrate support 205 and stem 126. In one embodiment, the body of the substrate support 205 is made from an aluminum material while each of the structures 215 disposed on the support surface 210 are made of or coated with a ceramic material, such as aluminum oxide.

FIG. 2B is an isometric bottom view of one embodiment of a pedestal 128. The stem 126 includes a first end that is coupled to the substrate support 205 and a base assembly 129 at a second end opposite the substrate support 205. In this embodiment, the base assembly 129 includes a slotted conductive portion 225 that is coupled to and/or containing a dielectric plug 230. In one embodiment, the slotted conductive portion 225 may be configured as a plug or a male interface adapted to mate with the power box 103 (FIG. 1). In this embodiment, the conductive portion 225 may be circular in cross-section having slots formed at least partially through an outer surface or wall. The dielectric plug 230 may be configured as a socket or a female interface or, alternatively, comprising a portion or portions that are configured as a socket or female interface adapted to receive or mate with electrical connections within the power box 103. In this embodiment, the slotted conductive portion 225 may be an integral extension of the stem 126 and made of an aluminum material, while the dielectric plug 230 is made of a PEEK resin.

The base assembly 129 also includes the circumferential ring 135 adapted to receive an o-ring 240 that interfaces with the power box 103 of FIG. 1. In this embodiment, the slotted conductive portion 225 includes an opening adapted to receive the dielectric plug 230 and the dielectric plug 230 fastens to the slotted conductive portion 225. The dielectric plug 230 also includes openings or sockets formed therein to receive electrical leads from the power box 103.

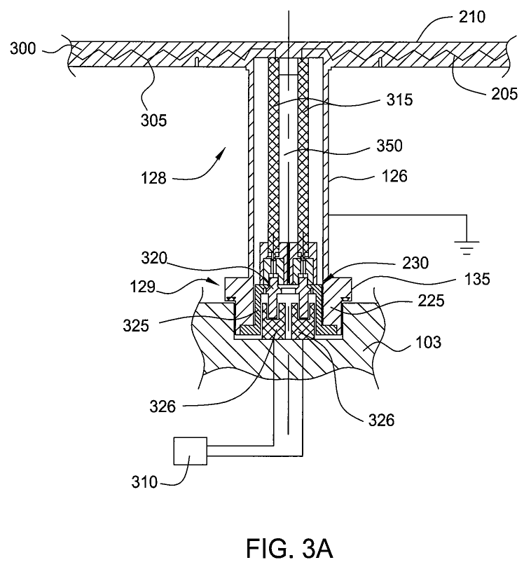

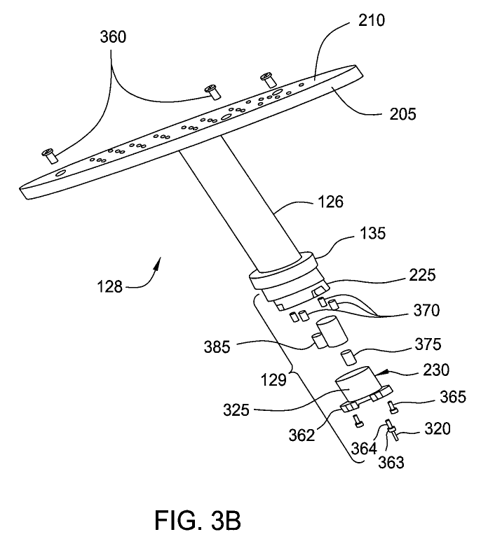

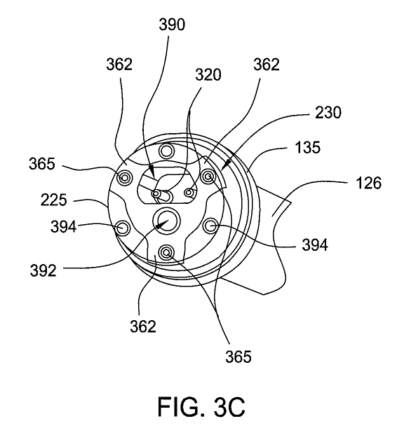

FIG. 3A is a cross sectional view of a portion of one embodiment of a pedestal 128 having a stem 126 coupled to a power outlet or power box 103 as shown in FIG. 1. The substrate support 205 includes an embedded heating element, such as a resistive heater 305 disposed or encapsulated in a conductive body 300. In one embodiment, the body 300 is made of a material consisting of a conductive metal, such as aluminum. The resistive heater 305 is coupled to a power source 310 disposed in the power box 103 by conductive leads 315 disposed in the stem 126. The stem 126 also includes a longitudinal channel or hole 350 adapted to receive a thermocouple (not shown). In this embodiment, the dielectric plug 230 includes one or more conductive plugs 320 disposed therein to couple the conductive leads 315 with a respective socket 326 disposed in the power box 103. In one embodiment, the conductive plugs 320 are multicontact plugs. The conductive leads 315 and the conductive plugs 320 may be electrically biased during operation, but are electrically isolated from the slotted conductive portion 225, the stem 126, and substrate support 205 by a peripheral wall 325 of the dielectric plug 230.

In one embodiment, the stem 126 and substrate support 205 are made of aluminum and are electrically grounded. The aluminum material encapsulates the heating element and acts an effective RF shield for the resistive heater 305. The RF shielding by the aluminum material eliminates need for band pass filters to filter off RF coupling to the resistive heater 305, which may be needed in heated pedestals made of different materials, such as ceramic. The design of the electrical interface using conductive plugs 320 as power terminals for the resistive heater 305 enables standard gauge wires and connectors from the power box 103 to be used as opposed to custom designed electrical connectors. The conductive plugs 320 are mounted on a unique base design comprising a PEEK resin. The conductive plugs 320 comprise a power terminal assembly, which is mechanically supported by the dielectric plug 230 which fastens onto the conductive portion 225 of the base assembly 129. The PEEK resin electrically insulates the live power terminals (conductive plugs 320) against the grounded heater body (substrate support 205 and stem 126). Thus, the pedestal 128 minimizes costs by the elimination of band-pass filters and utilizes less-expensive aluminum material, which significantly reduces cost of ownership. Further, the pedestal 128 as described herein may be retrofitted to replace original pedestals in existing chambers without extensive redesign and/or downtime.

FIG. 3B is an isometric exploded view of another embodiment of a pedestal 128. As shown, a plurality of sleeves or inserts 360, which may be made of a ceramic material, may be received by openings 220 (FIGS. 2A and 2B) disposed in the substrate support 205. The inserts 360 are adapted to receive lift pins 161 (FIG. 1). The base assembly 129 includes the slotted conductive portion 225 and the dielectric plug 230. The slotted conductive portion 225 includes radial slots adapted to receive extended members or ears 362 disposed ton a lower portion of the dielectric plug 230. The slotted conductive portion 225 and dielectric plug 230 are coupled to each other by fasteners 365, such as bolts or screws. In one embodiment, the fasteners 365 couple with respective threaded inserts 370 that are coupled to or disposed in the conductive portion 225. In one embodiment, the threaded inserts 370 comprise HELICOIL® inserts.

The conductive plugs 320 (only one is shown) include a shaft having a shoulder section 363 adapted as a stop or coupling section adapted to retain the conductive plug 320 in a cap section of the dielectric plug 230. The conductive plug 320 may also include a threaded end 364 adapted to screw into a conductive insert 375 having female threads. In one embodiment, the conductive plugs 320 are made of a brass material and plated with silver (Ag), and the conductive insert 375 is made of a brass material. The conductive insert 375 may be inserted into an insulative jacket 380 that may be made of a dielectric material, such as a PEEK resin. A guide member 385 for guiding and mounting of a thermocouple (not shown) may be coupled to or disposed adjacent the jacket 380 to extend therefrom. The guide member 385 may be made of an aluminum material.

FIG. 3C is a bottom isometric view of a base assembly 129. The dielectric plug 230 includes a substantially circular shaped body adapted to fit snugly in the slotted conductive portion 225. In one embodiment, each of the ears 362 extend radially outward from the body and are substantially equally spaced. In one embodiment, each of the ears 362 are positioned at equal angular increments, such as at 120 degree intervals. The body of the dielectric plug 230 also includes a plurality of recesses or openings, such as an opening 390 and an opening 392. In one embodiment, the opening 390 is a female interface having a trapezoidal shape that is utilized to receive a male plug that is disposed on the power box 103 (not shown). One or more conductive plugs 320 are housed within the opening 390. The opening 392 may be adapted as a female interface to receive a portion of a thermocouple (not shown) and/or a signal line that couples with a thermocouple. The bottom surface of the conductive portion also includes one or more recesses or openings 394, which may be adapted for indexing pins or mounting interfaces. In one embodiment, at least one of the openings 394 is adapted to receive a grounding device, such as a pin made of a conductive material.

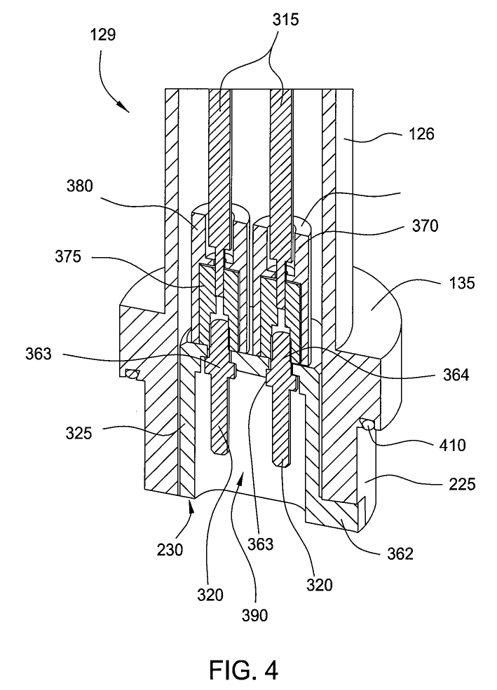

FIG. 4 is a cross-sectional view of one embodiment of a base assembly 129. The circumferential ring 135 includes a groove formed therein to receive a seal 410, such as an o-ring. The seal 410 may be made of an insulative material or a conductive material to facilitate grounding of the slotted conductive portion 225. In this embodiment, the conductive plugs 320 are shown coupled to a respective conductive insert 375. In one embodiment, each of the conductive inserts 375 are electrically isolated from other conductive portions of the base assembly 129 and each other by an insulative jacket 380. Each insulative jacket 380 may be made from an insulative material, such as a PEEK resin. In one embodiment, at least a portion of a conductive lead 315 extends at least partially into both of the insulative jacket 380 and the conductive insert 375 to put the conductive lead 315 in electrical communication with the conductive plug 320. In one aspect, the conductive plugs 320 are not in contact with the conductive leads 315.

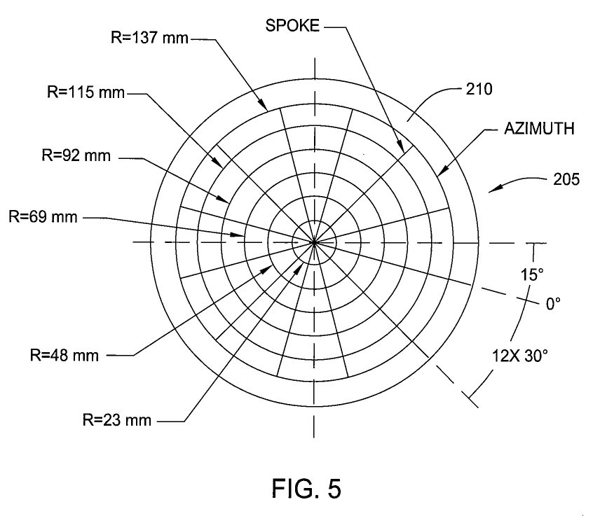

FIG. 5 is a schematic top view of a substrate support 205 of a pedestal 128 as described herein. The substrate support 205 is exemplarily sized for use in a 300 mm substrate application. To aide in explaining the invention and examples, the support surface 210 of substrate support 205 is graphically divided into seven separate concentric circles. The inner radius of each concentric circle is termed an azimuth. The azimuths lie at radii of 23 mm, 46 mm, 69 mm, 92 mm, 115 mm, and 137 mm. FIG. 5 is further graphically divided into spokes. The spokes radiate outward from the center of the circle. Spokes occur every 30 degrees, creating 12 in total. Including the center point, there are 73 points of intersection on the support surface 210 (12 spokes intersecting 6 azimuths, including the center radius).

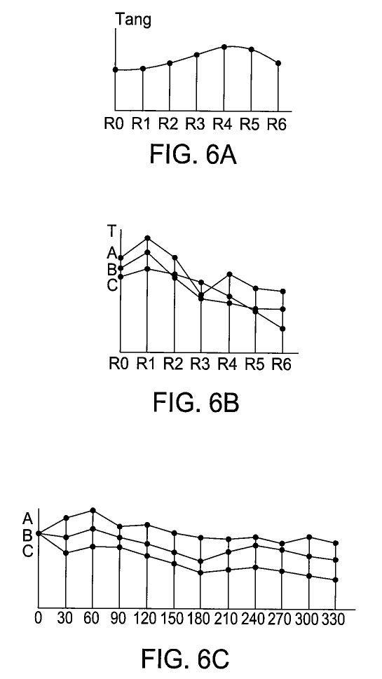

FIG. 6A is a graphical representation of the average temperature profile around each azimuth (R0=center of support surface 210, R6=outer most azimuth). Temperature measurements around the azimuth were taken at the spoke intersections. In this example, a pedestal 128 was used to support a 300 mm silicon carbide wafer having a thickness of 7 mm. The heater temperature was set at 400° C., and the pressure was set at 4 Torr. Argon was flowed through the chamber at a rate of 2 SLM. The standard base temperature remained at 75±1° C. The average temperature of the pedestal at each azimuth was between 389° C. and 392° C.

FIG. 6B is a graphical representation of the temperature range around each of the 6 azimuths. The data in FIG. 6B was collected under the same process parameters as the above example, during three separate runs (Runs A, B, and C). The range consists of 12 points around each azimuth (30°, 60°, 90°, . . . , 330°.), where the azimuths intersect the spokes. The range of the temperatures for azimuths R1-R6, individually, was typically less than 7° C. For instance, in one example the range of the temperature was about 5° C. on the second azimuth. For purposes of the examples, range of temperature is defined as the difference between the maximum value and the minimum value for any data set.

FIG. 6C is a graphical representation of the temperature range along each of the 12 spokes. The data in FIG. 6C was collected under the same process parameters as the above example. For three separate runs (Runs A, B, and C), the range of the temperature along the length of each spoke at azimuth intersections was calculated. The range of the temperature along each spoke for the three runs was between about 3° C. and about 8° C. For instance, in one run, the range of the temperature on the 60° spoke was about 5° C.

In one embodiment, a method of depositing thin films on a substrate is described using the dual processing regions 120A, 120B. The method includes providing at least one substrate in each processing region of the processing chamber on a respective pedestal 128 disposed therein. The pedestal 128 includes a substrate support 205 comprising a conductive material, a resistive heater 305 encapsulated within the substrate support, and a stem 126 comprising a conductive material coupled to the substrate support at a first end. The substrate support also includes a base assembly 129 configured as a mating interface at an opposing end. The mating interface includes a dielectric plug 230 that includes at least one exposed electrical connector being adapted to couple to a power outlet disposed on the processing chamber and being electrically isolated from the hollow shaft. The method also includes flowing one or more reactive gases to at least one of the processing regions 120A, 120B and generating a plasma using RF energy between the showerhead assembly 142 and the substrate support 205. In one embodiment, the reactive gas may be flowed in a carrier gas, such as hydrogen.

While the foregoing is directed to embodiments of the invention, other and further embodiments of the invention may be devised without departing from the basic scope thereof, and the scope thereof is determined by the claims that follow.

What is claimed is:

1. A pedestal for a semiconductor processing chamber, comprising:
a substrate support comprising a conductive material;
a heating element encapsulated within the substrate support; and
a hollow shaft comprising a conductive material coupled to the substrate support at a first end and a mating interface at an opposing end, the mating interface comprising a dielectric plug that includes at least one exposed electrical connector being adapted to couple to a power outlet disposed on the processing chamber and being electrically isolated from the hollow shaft.

2. The pedestal of claim 1, wherein the mating interface further comprises:
a plurality of slots formed at least partially through an outer surface thereof.

3. The pedestal of claim 2, wherein the dielectric plug comprises a plurality of extended members that mate with a respective slot.

4. The pedestal of claim 3, wherein the dielectric plug comprises a circular cross-section and each of the plurality of extended members extend radially therefrom.

5. The pedestal of claim 4, wherein the plurality of extended members are equally spaced.

6. The pedestal of claim 1, wherein the mating interface further comprises:
a circumferential ring disposed on an outer surface thereof.

7. The pedestal of claim 6, wherein the circumferential ring comprises an o-ring adapted to facilitate sealing of the processing chamber.

8. The pedestal of claim 1, wherein the substrate support includes a substrate receiving surface comprising a plurality of protrusions disposed on a support surface.

9. The pedestal of claim 8, wherein each of the plurality of protrusions are made of or coated with a ceramic material.

10. The pedestal of claim 1, wherein the at least one exposed electrical connector is in electrical communication with a conductive lead disposed in the hollow shaft.

11. A pedestal for a semiconductor processing chamber, comprising:
a substrate support comprising a conductive material;
a heating element encapsulated within the substrate support;
a hollow shaft comprising a conductive material coupled to the substrate support at a first end and a base assembly at an opposing end, the base assembly comprising:
a slotted conductive portion having an interior volume; and
a dielectric plug disposed in the interior volume, the dielectric plug comprising one or more conductive members extending longitudinally therethrough, each of the one or more conductive members being electrically isolated from the slotted conductive portion.

12. The pedestal of claim 11, wherein at least a portion of each of the one or more conductive members extend out of the base assembly.

13. The pedestal of claim 11, wherein the slotted conductive portion is an extension of the hollow shaft.

14. The pedestal of claim 11, wherein the dielectric plug comprises a plurality of extended members that mate with a respective slot in the slotted conductive portion.

15. The pedestal of claim 14, wherein the dielectric plug comprises a circular cross-section and each of the plurality of extended members extend radially therefrom.

16. The pedestal of claim 15, wherein the plurality of extended members are equally spaced.

17. A pedestal for a semiconductor processing chamber, comprising:
a substrate support coupled to a hollow shaft, each of the substrate support and the hollow shaft comprising an aluminum material, the hollow shaft including at least two conductive leads coupled to a heating element encapsulated within the substrate support; and
a base assembly coupled to the hollow shaft opposite the substrate support, the base assembly comprising:
a slotted conductive portion having an interior volume; and
a dielectric plug disposed in the interior volume, the dielectric plug comprising one or more conductive members extending longitudinally therethrough, each of the one or more conductive members being electrically coupled to at least one of the at least two conductive leads by a conductive insert disposed in an insulative jacket.

18. The pedestal of claim 17, wherein the dielectric plug includes at least three extended members received in a respective slot of the slotted conductive portion.

19. The pedestal of claim 18, wherein the at least three extended members are equally spaced.

20. The pedestal of claim 18, wherein the dielectric plug comprises a circular cross-section and each of the at least three extended members extend radially therefrom.

21. The pedestal of claim 17, wherein the slotted conductive portion is an extension of the hollow shaft.

22. The pedestal of claim 17, wherein the base assembly further comprises:
a circumferential ring disposed on an outer surface thereof.

23. The pedestal of claim 22, wherein the circumferential ring comprises a seal.

24. The pedestal of claim 17, wherein the substrate support includes a substrate receiving surface comprising a plurality of protrusions disposed on a support surface.

25. The pedestal of claim 24, wherein each of the plurality of protrusions are made of or coated with a ceramic material.
